(19) United States
(12) Patent Application Publication
(10) Pub. No.: US 2026/0155201 A1
(43) Pub. Date: Jun. 4, 2026

(54) SEMICONDUCTOR DEVICE EQUIPPED WITH GLOBAL COLUMN REDUNDANCY

(71) Applicant: MICRON TECHNOLOGY, INC., BOISE, ID (US)

(72) Inventors: Mamoru Nishizaki, Yokohama (JP); Junichiro Odagiri, Sagamihara-shi (JP); Haruka Momota, Chofu-shi (JP)

(73) Assignee: MICRON TECHNOLOGY, INC., Boise, ID (US)

(21) Appl. No.: 19/394,594

(22) Filed: Nov. 19, 2025

Related U.S. Application Data
(60) Provisional application No. 63/726,853, filed on Dec. 2, 2024.

(51) Int. Cl. G11C 29/00; G11C 11/4091

(52) U.S. Cl. CPC G11C 29/702; G11C 11/4091; G11C 29/785

(57) ABSTRACT

An example apparatus includes a second bit line pair for substituting for a defective one of first bit line pairs, a sense amplifier circuit configured to amplify a potential difference between the second bit line pair, first and second local I/O lines coupled to the second bit line pair via a column switch, a sub-amplifier circuit configured to drive a main I/O line based on a potential difference between the first and second local I/O lines, a precharge circuit configured to precharge the first and second local I/O lines to a first power potential responsive to a first control signal, and a discharge circuit configured to discharge the second local I/O line to a second power potential different from the first power potential responsive to a second control signal.

### CROSS-REFERENCE TO RELATED APPLICATIONS

This application claims the filing benefit of U.S. Provisional Application No. 63/726,853, filed December 2, 2024. This application is incorporated by reference herein in its entirety and for all purposes.

### BACKGROUND

As a method for replacing a defective bit line with a spare bit line, a local column redundancy method that prepares a spare bit line for each column plane and a global column redundancy method that prepares a spare column plane and replaces a defective bit line in each column plane with a bit line in the spare column plane are known. The local column redundancy method has an advantage that even in a case where two or more of a plurality of bit lines belonging to different column planes and being selected by the same column address at the same time are defective, the defective bit lines can be replaced with spare bit lines. However, in the local column redundancy method, if there is even one defective bit line, all bit lines selected by the corresponding column address at the same time are replaced with spare bit lines, and it is therefore necessary to prepare many spare bit lines. On the other hand, the global column redundancy method has a high relief efficiency because only a defective bit line is replaced with a bit line in the spare column plane.

However, the global column redundancy method has the following problem. In a case where no access is made to a spare column plane in a read operation, a pair of local I/O lines assigned to the spare column plane is maintained in a precharge state. In this case, a main I/O line is discharged by the pair of local I/O lines being in a precharge state, thus causing an increase in current consumption.

### BRIEF DESCRIPTION OF THE DRAWINGS

FIG. 1 is a schematic plan view showing a configuration of main parts of a semiconductor memory device according to an embodiment of the present disclosure;

FIG. 2 is a schematic diagram for explaining a function of a GCR mat;

FIG. 3 is a schematic diagram for explaining a configuration of a normal mat;

FIG. 4 is a circuit diagram for explaining a coupling relation between a memory cell and a main I/O line;

FIG. 5A and FIG. 5B are schematic diagrams for explaining a layout example of a column selection line;

FIG. 6 is a circuit diagram of a column control circuit configured by a sense amplifier and a column switch;

FIG. 7 is a circuit diagram of a source driver circuit;

FIG. 8 is a circuit diagram of a sub-amplifier;

FIG. 9 is a schematic diagram for explaining a configuration of a sense amplifier region assigned to the normal mat;

FIG. 10 is a schematic diagram for explaining a configuration of a sense amplifier region assigned to a ECC mat and a GCR mat;

FIG. 11A and FIG. 11B are circuit diagrams of a precharge circuit;

FIG. 12 is a schematic plan view for explaining a layout of the precharge circuit;

FIG. 13 is a schematic diagram for explaining a layout of wiring for coupling local I/O lines to the precharge circuit;

FIG. 14A and FIG. 14B are diagrams showing the wiring shown in FIG. 13 in more detail;

FIG. 15A and FIG. 15B are schematic diagrams for explaining a layout of wiring for coupling to the precharge circuit; and

FIG. 16 is a circuit diagram of a precharge circuit according to a modification.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

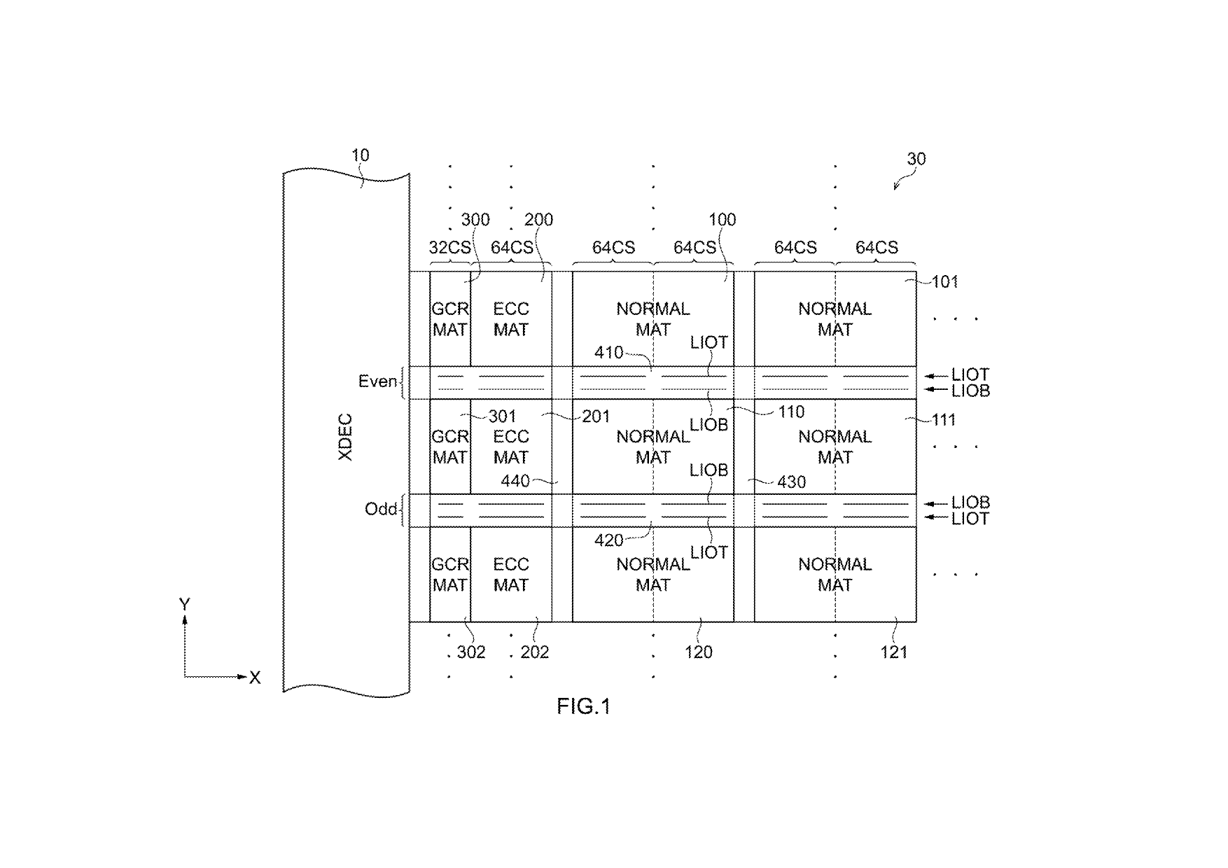

FIG. 1 is a schematic plan view showing a configuration of main parts of a semiconductor memory device according to an embodiment of the present disclosure. The semiconductor memory device shown in FIG. 1 is a DRAM, for example, and includes a memory cell array 30 including a plurality of normal mats 100, 101, 110, 111, 120, and 121, a plurality of ECC mats 200 to 202, and a plurality of GCR mats 300 to 302. The normal mats 100, 101, 110, 111, 120, and 121 are storage areas for retaining user data. The ECC mats 200 to 202 are memory cell arrays for storing an error correction code (ECC) to be added to user data. The GCR mats 300 to 302 are memory cell arrays, configured by spare bit lines, for substituting for a defective bit line included in the normal mats 100, 101, 110, 111, 120, and 121 or the ECC mats 200 to 202. In the example shown in FIG. 1, one normal mat includes 128 bit lines, one ECC mat includes 64 bit lines, and one GCR mat includes 32 bit lines. Sense amplifier regions 410 and 420 are arranged on both sides of the normal mat 110 in a Y-direction, respectively. Word driver regions 430 and 440 are arranged on both sides of the normal mat 110 in an X-direction, respectively.

Local I/O lines LIOT and LIOB are arranged in the sense amplifier regions 410 and 420. In the example shown in FIG. 1, those local I/O lines LIOT and LIOB are divided into the local I/O lines LIOT and LIOB corresponding to 64 bit lines included in a normal mat and the local I/O lines LIOT and LIOB corresponding to other 64 bit lines in the normal mat. The memory cell array 30 has an open bit line structure. Therefore, half of the bit lines included in each mat are assigned to the sense amplifier region adjacent thereto on the +Y-direction side, and the other half are assigned to the sense amplifier region adjacent thereto on the -Y-direction side. In some examples, the X-direction may be perpendicular to the Y-direction.

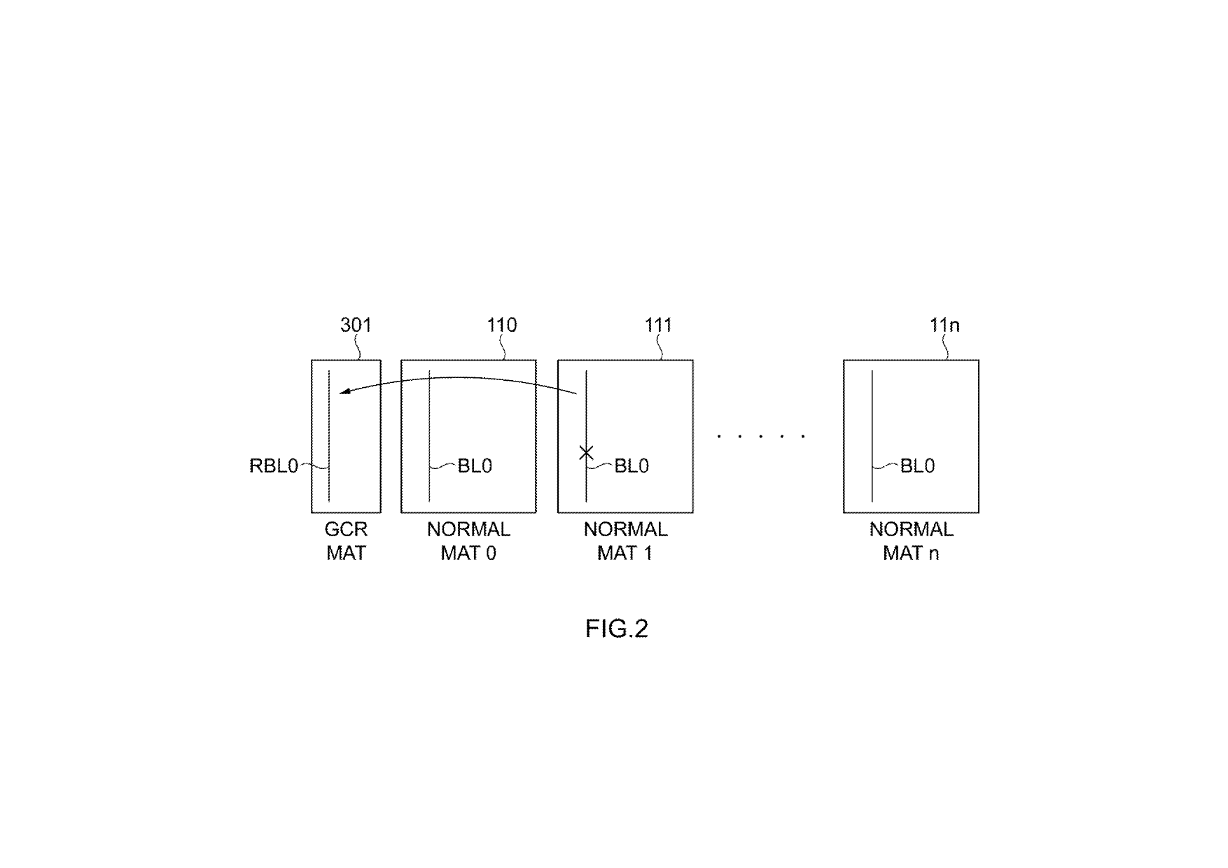

FIG. 2 is a schematic diagram for explaining a function of a GCR mat. The GCR mat 301 includes a plurality of spare bit lines. The bit lines included in the GCR mat 301 are accessed in place of a defective bit line included in any of the normal mats 110 to 11n. For example, a case where bit lines BL0 included in the normal mats 110 to 11n are selected at the same time by a certain column address is considered. Assuming that the bit line BL0 included in the normal mat 111 is defective, access to the normal mat 111 is replaced with access to the GCR mat 301, and a bit line RBL0 included in the GCR mat 301 is selected instead. The bit lines included in the GCR mat 301 can substitute for bit lines included in any of the normal mats 110 to 11n. However, in a case where two or more of the bit lines selected at the same time by the certain column address are defective, relief using the GCR mat 301 cannot be performed.

Meanwhile, when access to a column address with no defect is requested, bit lines respectively included in the normal mats 110 to 11n are selected, and no bit line in the GCR mat 301 is selected. Therefore, when a read operation is requested to a column address with no defect, the local I/O lines LIOT and LIOB corresponding to the GCR mat 301 are maintained in a precharge state. However, as described later, when the local I/O line LIOB is maintained in a precharge state in a read operation, a main I/O line MIO is discharged, and it is therefore necessary to precharge the main I/O line MIO again. In order to prevent this situation, the semiconductor memory device according to the present disclosure includes a discharge circuit for, in a case where the GCR mat 301 is unselected in a read operation, forcibly discharging the local I/O line LIOB.

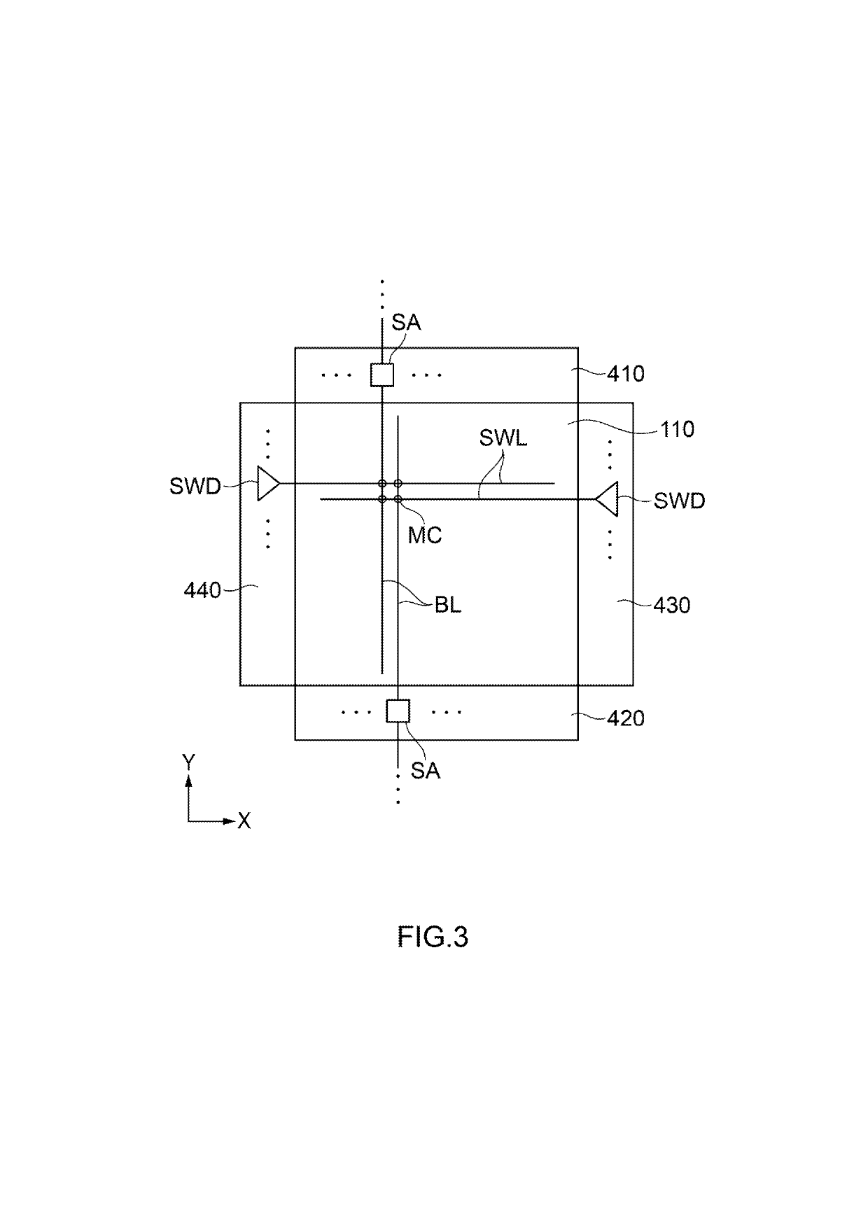

FIG. 3 is a schematic diagram for explaining a configuration of the normal mat 110. As shown in FIG. 3, a plurality of sub-word lines SWL extending in the X-direction, a plurality of bit lines BL extending in the Y-direction, and memory cells MC arranged at respective intersection points of the sub-word lines SWL and the bit lines BL are provided in the normal mat 110. The sub-word lines SWL are each driven by a sub-word driver SWD arranged in the word driver region 430 or 440 based on lower bits of a row address. Selection of a memory mat is performed by a row decoder 10 shown in FIG. 1 based on higher bits of the row address. The bit lines BL are each coupled to a sense amplifier SA arranged in the sense amplifier region 410 or 420. The ECC mats 200 to 202 and the GCR mats 300 to 302 each also have the same configuration as the normal mat 110 shown in FIG. 3 except that the number of bit lines BL is different.

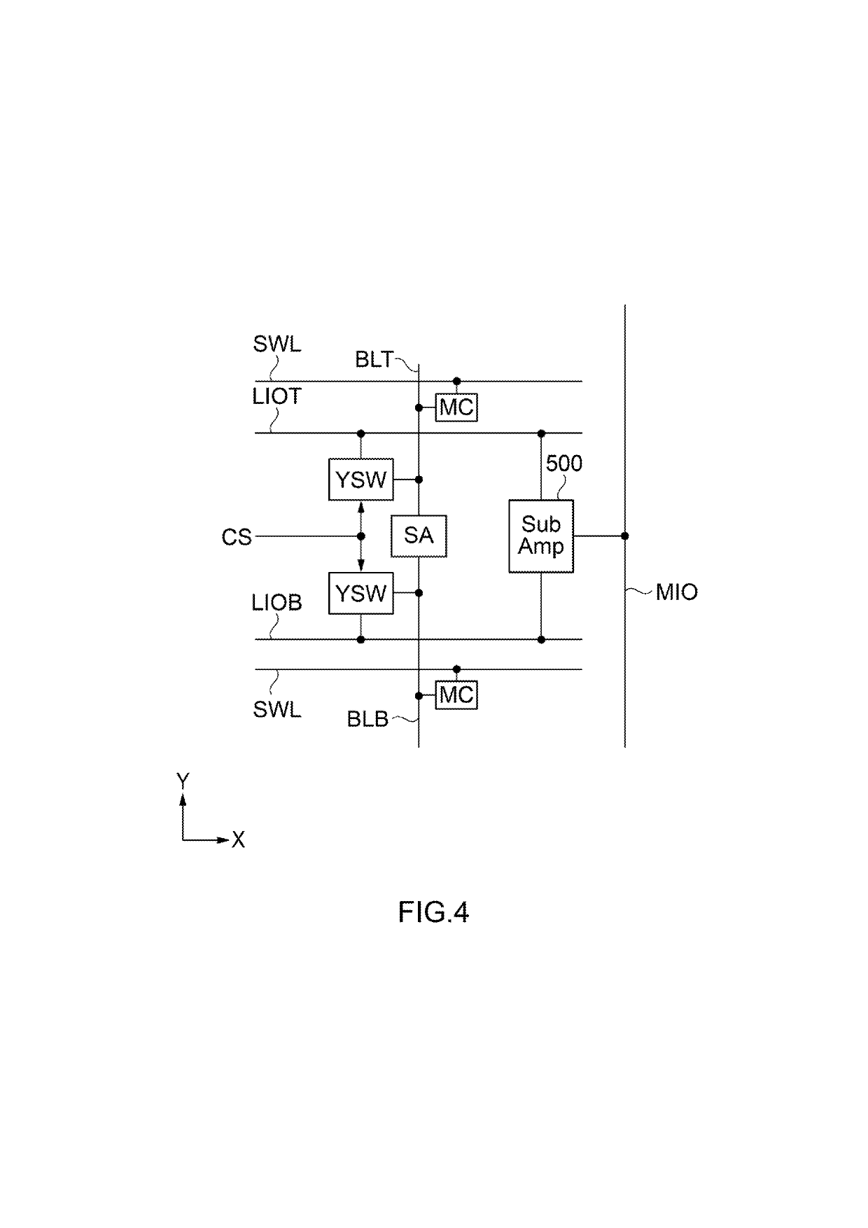

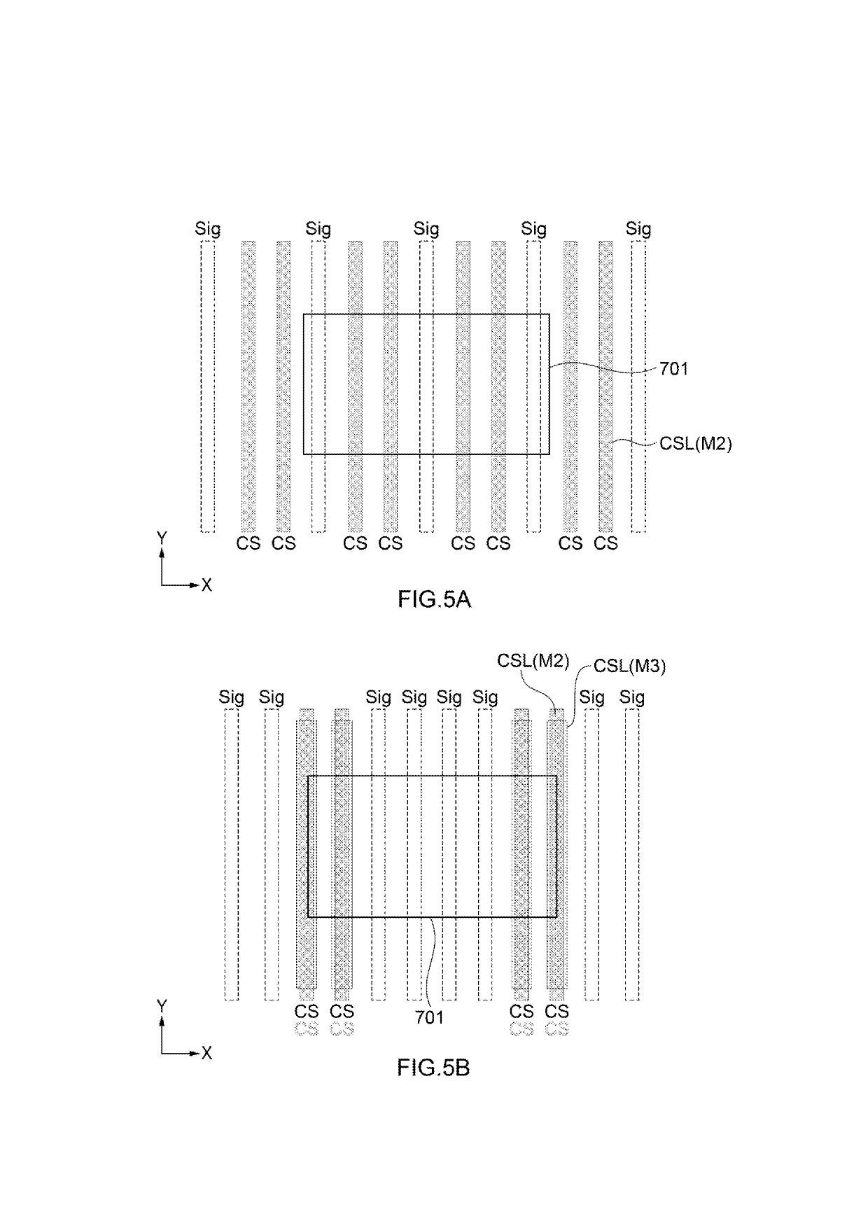

FIG. 4 is a circuit diagram for explaining a coupling relation between the memory cell MC and the main I/O line MIO. As shown in FIG. 4, the sense amplifier SA coupled to a pair of bit lines BLT and BLB is coupled to a pair of local I/O lines LIOT and LIOB via column switches YSW, when a corresponding column selection signal CS is activated. The local I/O lines LIOT and LIOB extend in the X-direction. The local I/O lines LIOT and LIOB are coupled to the corresponding main I/O line MIO via a sub-amplifier 500. The main I/O line MIO extends in the Y-direction. A column selection line supplying the column selection signal CS also extends in the Y-direction. A column selection line CSL may be laid out by using a single conductor layer (e.g., a conductor layer M2) on a sense amplifier region as shown in FIG. 5A, or may be laid out by using a plurality of conductor layers (e.g., conductor layers M2 and M3) on a sense amplifier region as shown in FIG. 5B. In the example shown in FIG. 5B, four column selection lines CSL(M3) formed in the conductor layer M3 are arranged to overlap four column selection lines CSL(M2) formed in the conductor layer M2.

In a case where the column selection lines CSL are laid out by using the conductor layer M2 as shown in FIG. 5A, the wiring density of lines Sig that can be laid out to extend in the Y-direction by using the conductor layer M2 on a sense amplifier region is 1/2 of the wiring density of the column selection lines CSL. Meanwhile, in a case where the column selection lines CSL are laid out by using the conductor layers M2 and M3 as shown in FIG. 5B, the wiring density of the lines Sig that can be laid out to extend in the Y-direction by using the conductor layer M2 on a sense amplifier region is double the wiring density of the column selection lines CSL. Accordingly, the flexibility of designing the conductor layer M2 on a sense amplifier region can be increased.

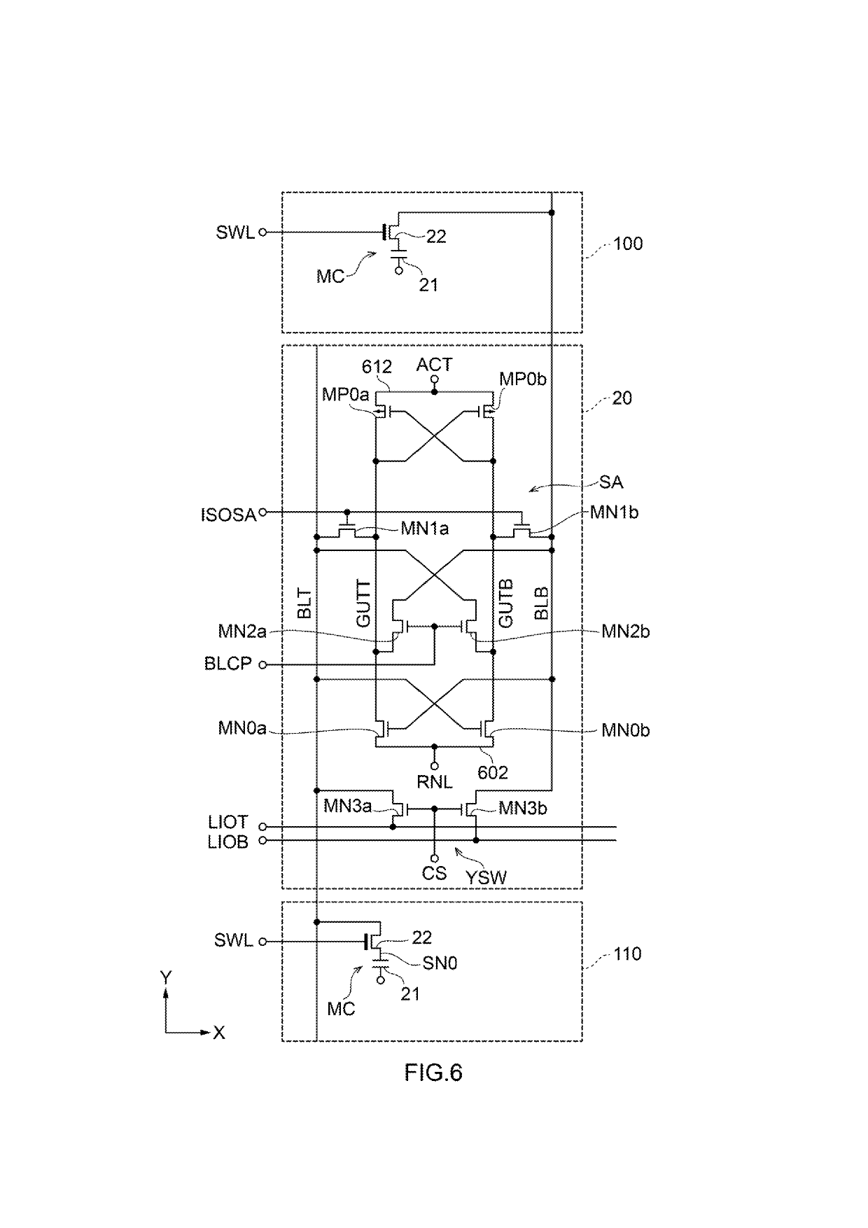

FIG. 6 is a circuit diagram of a column control circuit 20 configured by the sense amplifier SA and the column switch YSW. As shown in FIG. 6, the sense amplifier SA includes cross-coupled N-channel MOS transistors MN0a and MN0b and cross-coupled P-channel MOS transistors MP0a and MP0b. A source potential RNL is supplied to the sources of the transistors MN0a and MN0b via a source line 602. A source potential ACT is supplied to the sources of the transistors MP0a and MP0b via a source line 612. The gate electrode of the transistor MN0a is coupled to a bit line BLB, and the gate electrode of the transistor MN0b is coupled to a bit line BLT. The drain of the transistor MN0a is coupled to an internal line GUTT, and the drain of the transistor MN0b is coupled to an internal line GUTB. The internal line GUTT is coupled to the drain of the transistor MP0a and the gate electrode of the transistor MP0b and is also coupled to the bit line BLT via an N-channel MOS transistor MN1a. The internal line GUTB is coupled to the drain of the transistor MP0b and the gate electrode of the transistor MP0a and is also coupled to the bit line BLB via an N-channel MOS transistor MN1b. A control signal ISOSA is supplied to the gate electrodes of the transistors MN1a and MN1b in common. With this configuration, when the source potential RNL is driven to a low level and the source potential ACT is driven to a high level in a state where the control signal ISOSA has been activated to a high level, a potential difference generated between the bit line BLT and the bit line BLB is amplified by the sense amplifier SA. The memory cell MC configured by a cell capacitor 21 and a cell transistor 22 is coupled to the bit lines BLT and BLB. When any of the sub-word lines SWL is selected based on a row address, a potential difference is generated between the bit line BLT and the bit line BLB. Then, when the column selection signal CS is activated based on a column address to turn on a column switch configured by N-channel MOS transistors MN3a and MN3b, a pair of bit lines BLT and BLB are coupled to a pair of local I/O lines LIOT and LIOB.

The sense simplifier SA further includes N-channel MOS transistors MN2a and MN2b. The transistor MN2a is coupled between the internal line GUTT and the bit line BLB. The transistor MN2b is coupled between the internal line GUTB and the bit line BLT. A control signal BLCP is supplied to the gate electrodes of the transistors MN2a and MN2b in common. The transistors MN2a and MN2b configure a compensation circuit that compensates a difference between threshold voltages of the transistors MN0a and MN0b.

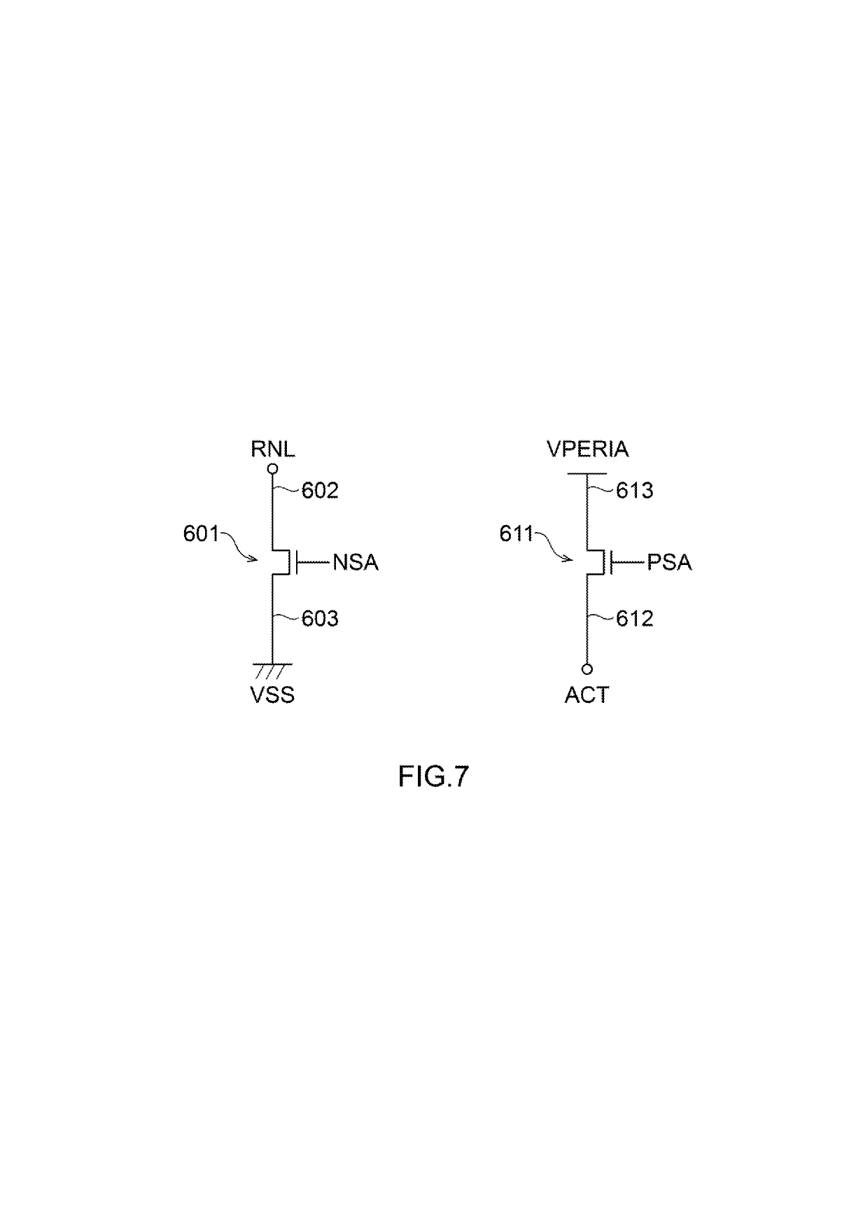

The source potential RNL is supplied by a source driver circuit 601 shown in FIG. 7. The source driver circuit 601 is configured by an N-channel MOS transistor coupled between the source line 602 supplying the source potential RNL and a line 603 to which a power potential VSS is supplied. The source potential ACT is supplied by a source driver circuit 611 shown in FIG. 7. The source driver circuit 611 is configured by an N-channel MOS transistor coupled between a line 613 to which a power potential VPERIA is supplied and the line 612 supplying the source potential ACT.

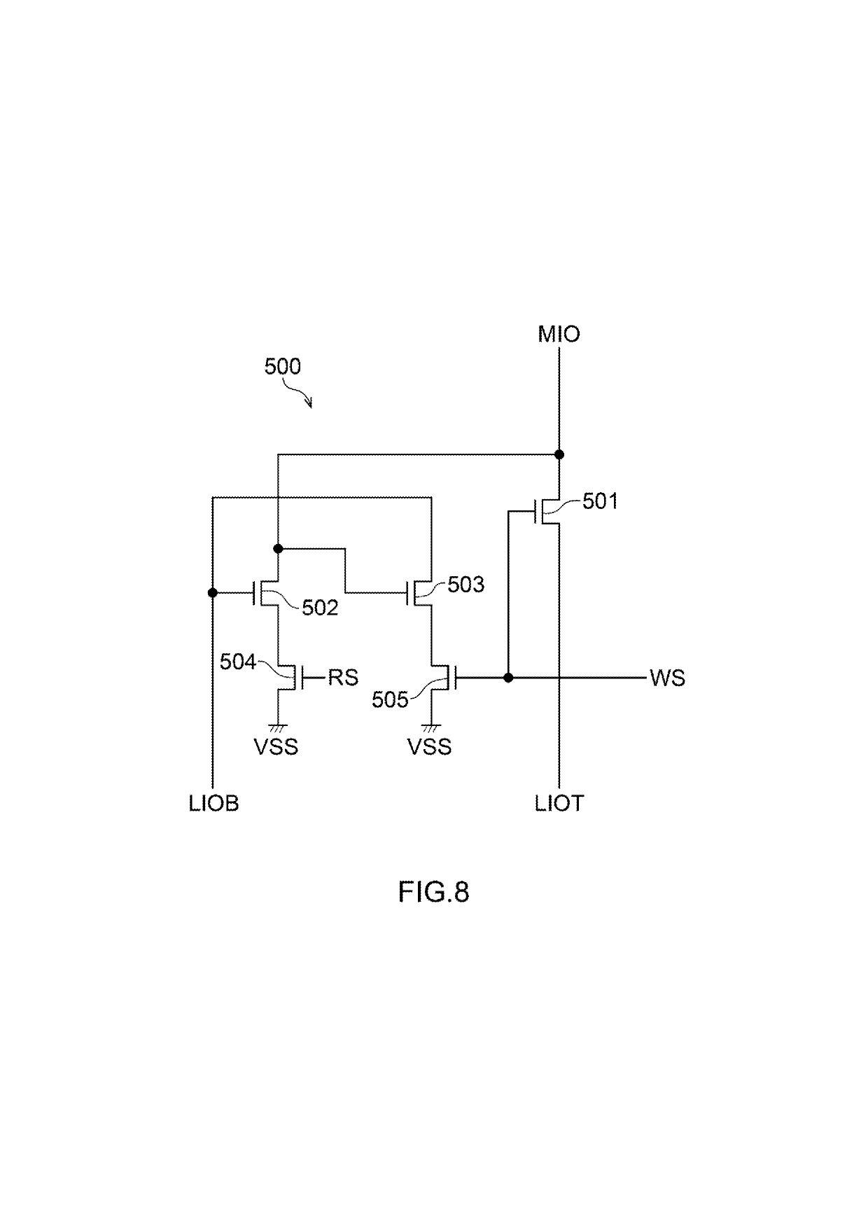

FIG. 8 is a circuit diagram of the sub-amplifier 500. As shown in FIG. 8, the sub-amplifier 500 includes N-channel MOS transistors 501 to 505. The transistor 501 is coupled between the local I/O line LIOT and the main I/O line MIO, and a write enable signal WS is supplied to the gate electrode of the transistor 501. The write enable signal WS is activated in a write operation. The transistors 502 and 504 are coupled in series between the main I/O line MIO and a power line to which a ground potential VSS is supplied. The gate electrode of the transistor 502 is coupled to the local I/O line LIOB. A read enable signal RS is supplied to the gate electrode of the transistor 504. The read enable signal RS is activated in a read operation. The transistors 503 and 505 are coupled in series between the local I/O line LIOB and the power line to which the ground potential VSS is supplied. The gate electrode of the transistor 503 is coupled to the main I/O line MIO. The write enable signal WS is supplied to the gate electrode of the transistor 505.

With this configuration, when the level of the main I/O line MIO is high in a write operation, the transistors 501, 503, and 505 are turned on, and therefore the local I/O line LIOT becomes high, and the local I/O line LIOB becomes low. On the other hand, when the level of the main I/O line MIO is low in a write operation, the transistors 501 and 505 are turned on, and therefore the local I/O line LIOT becomes low, whereas the local I/O line LIOB is maintained in a precharge state (high level). Further, when the local I/O line LIOT is at a high level and the local I/O line LIOB is at a low level in a read operation, the transistor 504 is turned on. However, since the transistor 502 is in an off state, the main I/O line MIO is maintained in a precharge state (high level). On the other hand, when the local I/O line LIOT is at a low level and the local I/O line LIOB is at a high level in a read operation, the transistors 502 and 504 are turned on, and therefore the main I/O line MIO becomes low. As described above, the sub-amplifier 500 converts a differential signal to a single-ended signal in a read operation and converts a single-ended signal to a differential signal in a write operation.

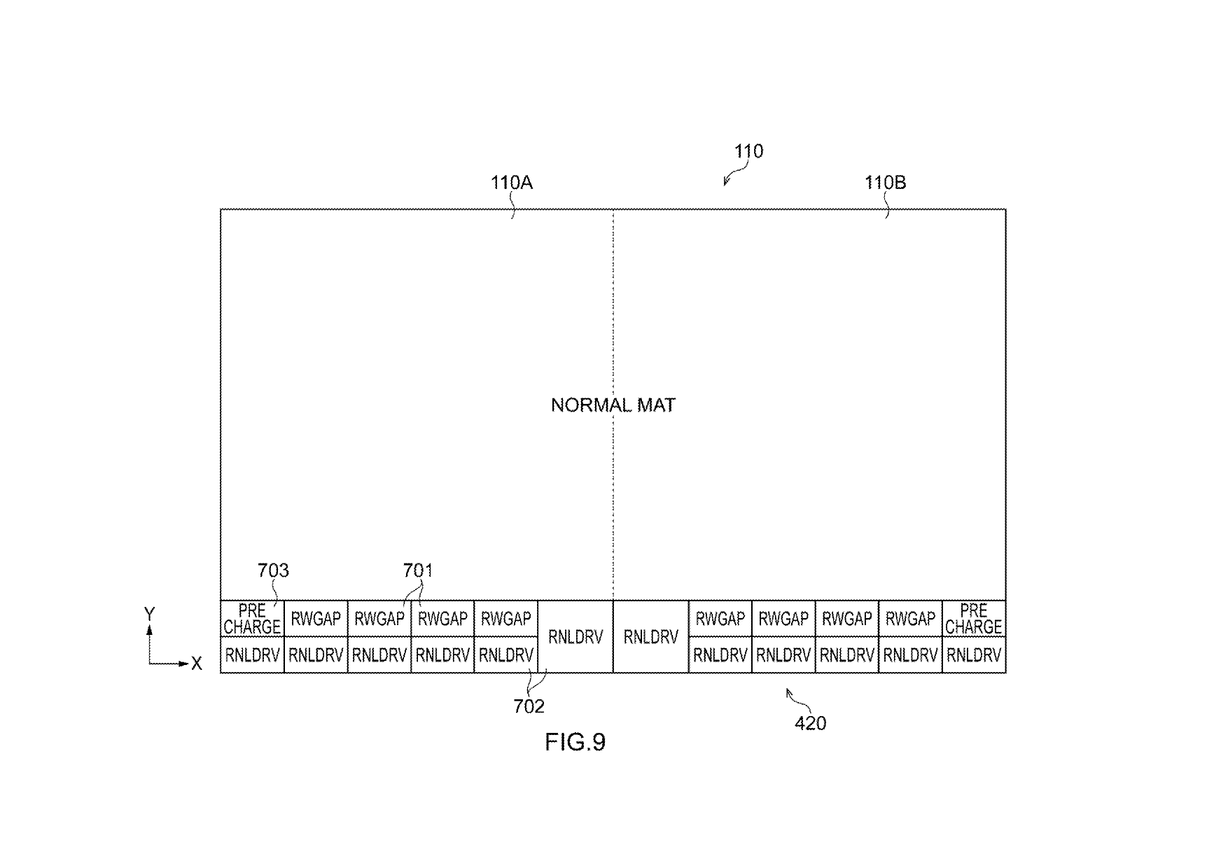

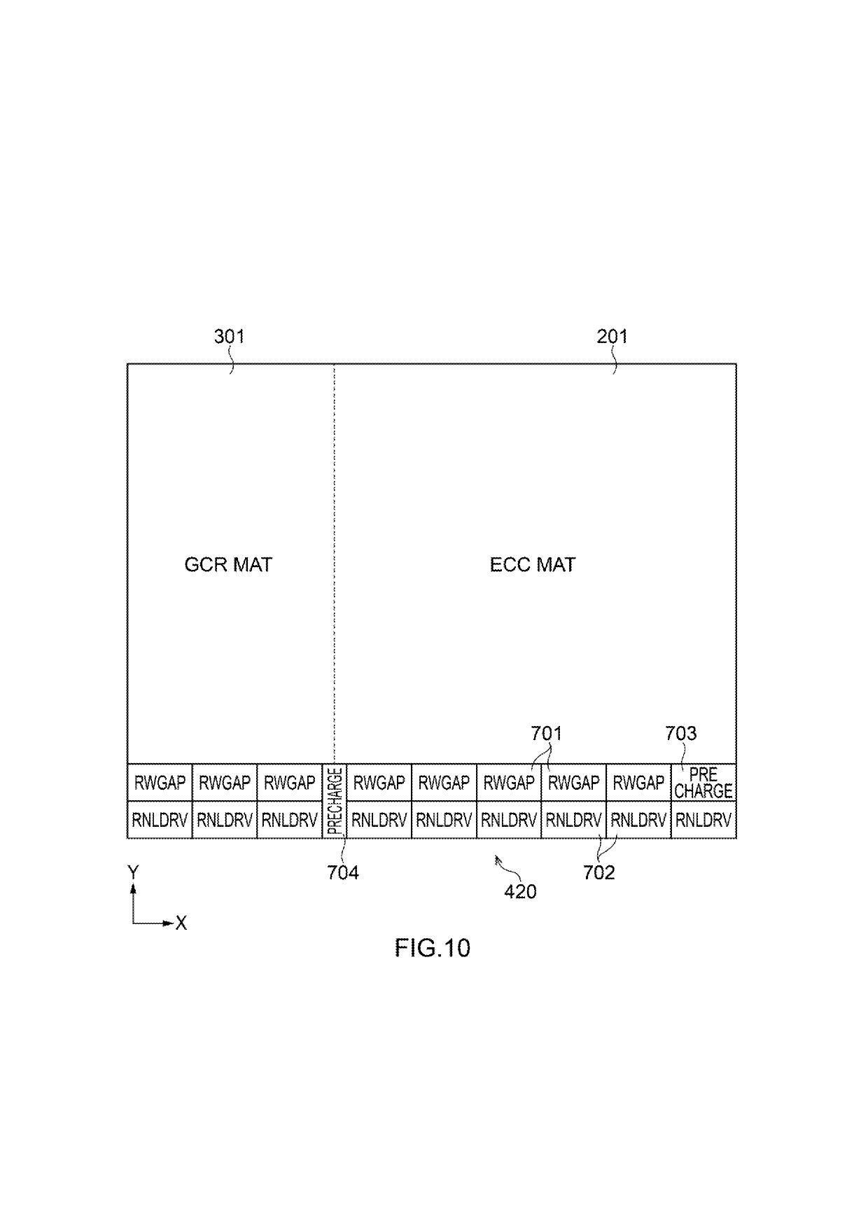

FIG. 9 is a schematic diagram for explaining a configuration of the sense amplifier region 420 assigned to the normal mat 110. FIG. 10 is a schematic diagram for explaining a configuration of the sense amplifier region 420 assigned to the ECC mat 201 and the GCR mat 301. As shown in FIG. 9, the normal mat 110 is divided into two mats 110A and 110B arranged in the X-direction. The layout in the sense amplifier region 420 assigned to the mat 110A and the layout in the sense amplifier region 420 assigned to the mat 110B are symmetric about the boundary between them. The sense amplifier region 420 includes a region 701 where the column control circuit 20 (the sense amplifier SA and the column switch YSW) is arranged, a region 702 where the source driver circuit 601 is arranged, and a region 703 where a precharge circuit precharging the local I/O lines LIOT and LIOB is arranged. As shown in FIG. 10, the sense amplifier region 420 assigned to the ECC mat 201 and the GCR mat 301 includes a region 704 where a precharge circuit for the GCR mat 301 is arranged, in addition to the regions 701 to 703.

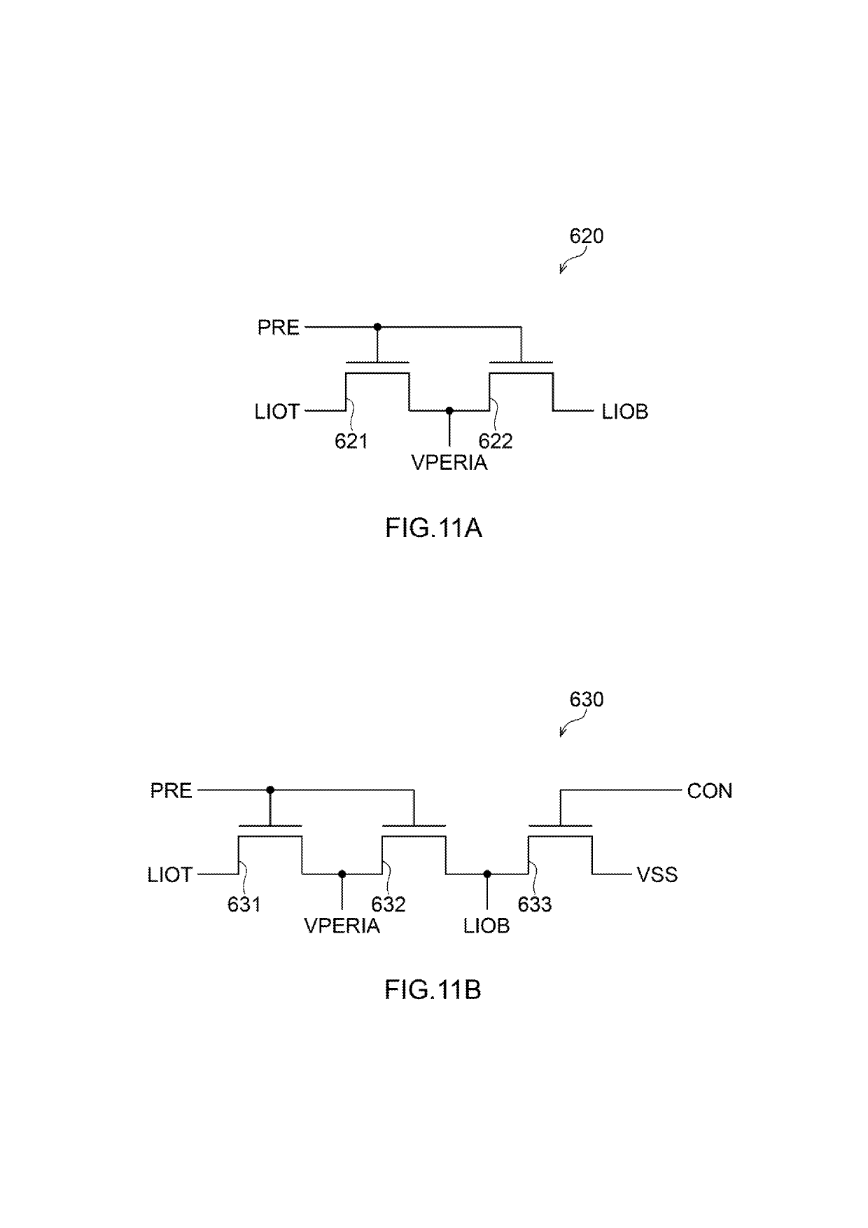

FIG. 11A is a circuit diagram of a precharge circuit arranged in the region 703. FIG. 11B is a circuit diagram of a precharge circuit arranged in the region 704. As shown in FIG. 11A, a precharge circuit 620 arranged in the region 703 is configured by N-channel MOS transistors 621 and 622. The transistor 621 is coupled between the local I/O line LIOT and a power line to which an array potential VPERIA is supplied. The transistor 622 is coupled between the local I/O line LIOB and the power line to which the array potential VPERIA is supplied. A precharge signal PRE is supplied to the gate electrodes of the transistors 621 and 622 in common. Accordingly, when the precharge signal PRE is activated to a high level, the local I/O lines LIOT and LIOB are precharged to the array potential VPERIA. The precharge signal PRE is activated to a high level while the memory cell array 30 is in a precharge state.

As shown in FIG. 11B, a precharge circuit 630 arranged in the region 704 is configured by N-channel MOS transistors 631 to 633. The transistor 631 is coupled between the local I/O line LIOT and the power line to which the array potential VPERIA is supplied. The transistor 632 is coupled between the local I/O line LIOB and the power line to which the array potential VPERIA is supplied. The transistor 633 is coupled between the local I/O line LIOB and a power line to which the ground potential VSS is supplied. The precharge signal PRE is supplied to the gate electrodes of the transistors 631 and 632 in common. A control signal CON is supplied to the gate electrode of the transistor 633. Accordingly, when the precharge signal PRE is activated to a high level, the local I/O lines LIOT and LIOB are precharged to the array potential VPERIA, and when the control signal CON is activated to a high level, the local I/O line LIOB is discharged to the ground potential VSS. The control signal CON is activated to a high level when the GCR mat is not selected in a read operation. When the GCR mat is selected in a read operation, the control signal CON is kept low.

The transistor 633 configures a discharge circuit that forcibly discharges the local I/O line LIOB when the GCR mat is not selected in a read operation. The control signal CON is activated when a read operation is requested to a column address with no defect. Accordingly, when a read operation is requested to a column address with no defect, the local I/O line LIOB corresponding to the GCR mat 301 is forcibly discharged. Consequently, the transistor 502 shown in FIG. 8 is turned off, so that the precharge state of the main I/O line MIO is maintained, and the main I/O line MIO is prevented from being charged and discharged unnecessarily.

The transistor 633 is not included in the precharge circuit 620 arranged in the region 703 but is included only in the precharge circuit 630 arranged in the region 704. Therefore, the precharge circuit 630 requires a larger occupied area than the precharge circuit 620.

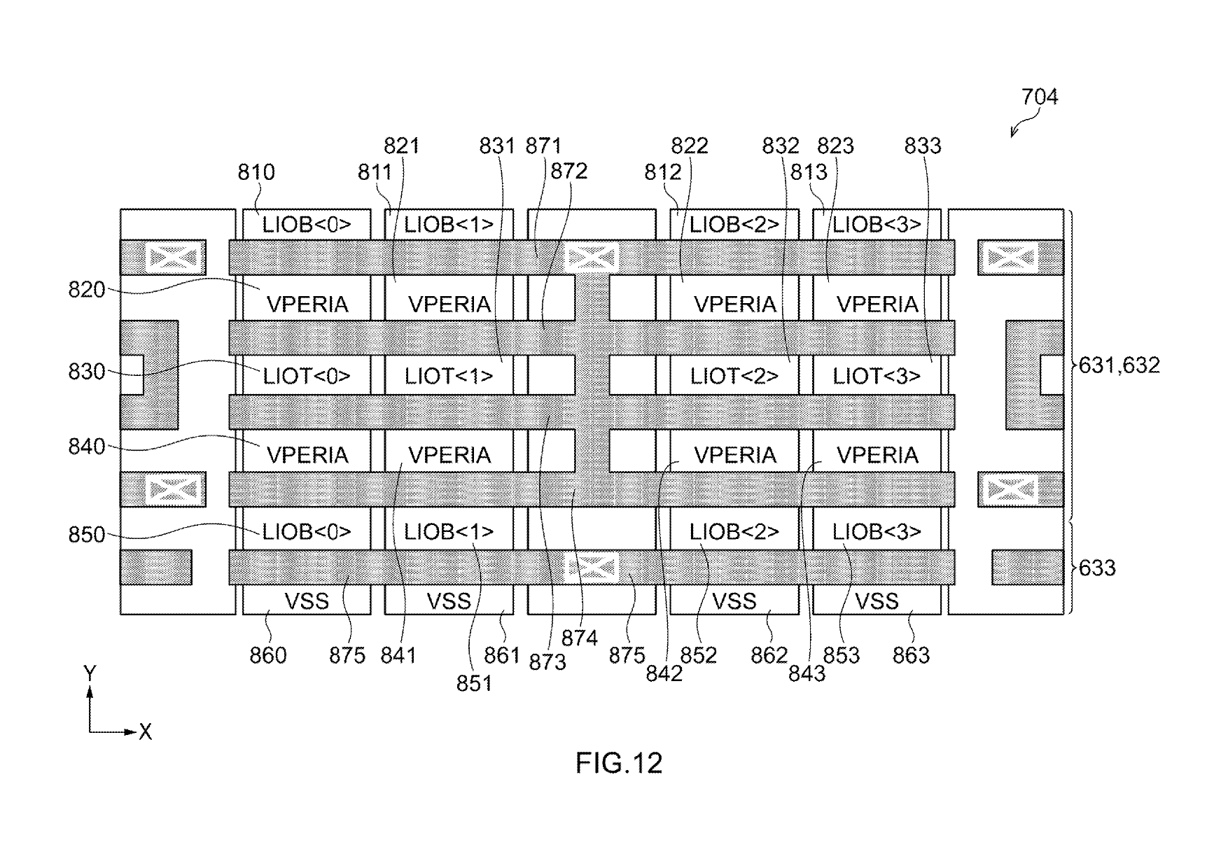

FIG. 12 is a schematic plan view for explaining a layout of the precharge circuit 630 arranged in the region 704. As shown in FIG. 12, diffusion regions 810 to 813 arrayed in the X-direction, diffusion regions 820 to 823 arrayed in the X-direction, diffusion regions 830 to 833 arrayed in the X-direction, diffusion regions 840 to 843 arrayed in the X-direction, diffusion regions 850 to 853 arrayed in the X-direction, and diffusion regions 860 to 863 arrayed in the X-direction are placed in the region 704. The diffusion regions 810 to 813 are coupled to local I/O lines LIOB0 to LIOB3, respectively. The diffusion regions 830 to 833 are coupled to local I/O lines LIOT0 to LIOT3, respectively. The diffusion regions 850 to 853 are coupled to the local I/O lines LIOB0 to LIOB3, respectively. The diffusion regions 820 to 823 and 840 to 843 are all coupled to a power line to which the array potential VPERIA is supplied. The diffusion regions 860 to 863 are all coupled to a power line to which the ground potential VSS is supplied.

A gate electrode 871 is arranged on a channel region located between the diffusion regions 810 to 813 and the diffusion regions 820 to 823. Accordingly, the diffusion regions 810 to 813, the diffusion regions 820 to 823, and the gate electrode 871 form half of the transistor 632 shown in FIG. 11B. A gate electrode 872 is arranged on a channel region located between the diffusion regions 820 to 823 and the diffusion regions 830 to 833. Accordingly, the diffusion regions 820 to 823, the diffusion regions 830 to 833, and the gate electrode 872 form half of the transistor 631 shown in FIG. 11B. A gate electrode 873 is arranged on a channel region located between the diffusion regions 830 to 833 and the diffusion regions 840 to 843. Accordingly, the diffusion regions 830 to 833, the diffusion regions 840 to 843, and the gate electrode 873 form the remaining half of the transistor 631 shown in FIG. 11B. A gate electrode 874 is arranged on a channel region located between the diffusion regions 840 to 843 and the diffusion regions 850 to 853. Accordingly, the diffusion regions 840 to 843, the diffusion regions 850 to 853, and the gate electrode 874 form the remaining half of the transistor 632 shown in FIG. 11B. The gate electrodes 871 to 874 are short-circuited to each other, and the precharge signal PRE is supplied to them in common.

A gate electrode 875 is arranged on a channel region located between the diffusion regions 850 to 853 and the diffusion regions 860 to 863. Accordingly, the diffusion regions 850 to 853, the diffusion regions 860 to 863, and the gate electrode 875 form the transistor 633 shown in FIG. 11B. The control signal CON is supplied to the gate electrode 875. Since both the transistors 631 and 632 have a configuration in which two transistors are coupled in parallel as described above, the transistors 631 and 632 have a size double the size of the transistor 633.

In the layout shown in FIG. 12, half of the transistor 632 and the transistor 633 share the transistor diffusion regions 850 to 853. Therefore, the precharge circuit 630 shown in FIG. 11B can be laid out in a high density. Accordingly, in spite of addition of the transistor 633 as compared with the precharge circuit 620, the precharge circuit 630 can be arranged within the sense amplifier regions 410 and 420 without arranging the added transistor 633 in another region, for example, the row decoder 10.

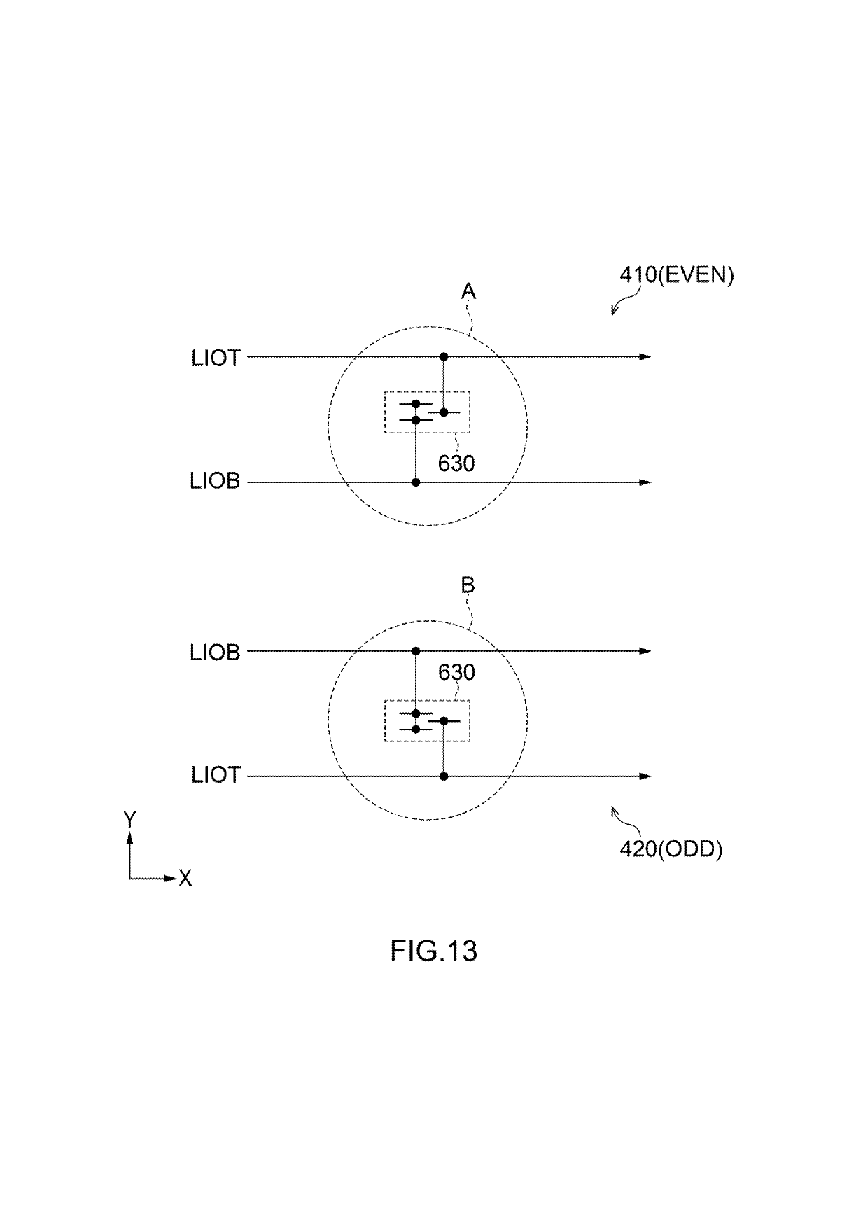

As shown in FIG. 1, the local I/O lines LIOT and LIOB in the sense amplifier region 410 on the EVEN side and the local I/O lines LIOT and LIOB in the sense amplifier region 420 on the ODD side are laid out symmetrically with respect to the normal mat 110. Therefore, as shown in FIG. 13, wiring A for coupling the local I/O lines LIOT and LIOB in the sense amplifier region 410 on the EVEN side to the precharge circuit 630 and wiring B for coupling the local I/O lines LIOT and LIOB in the sense amplifier region 420 on the ODD side to the precharge circuit 630 are also laid out symmetrically.

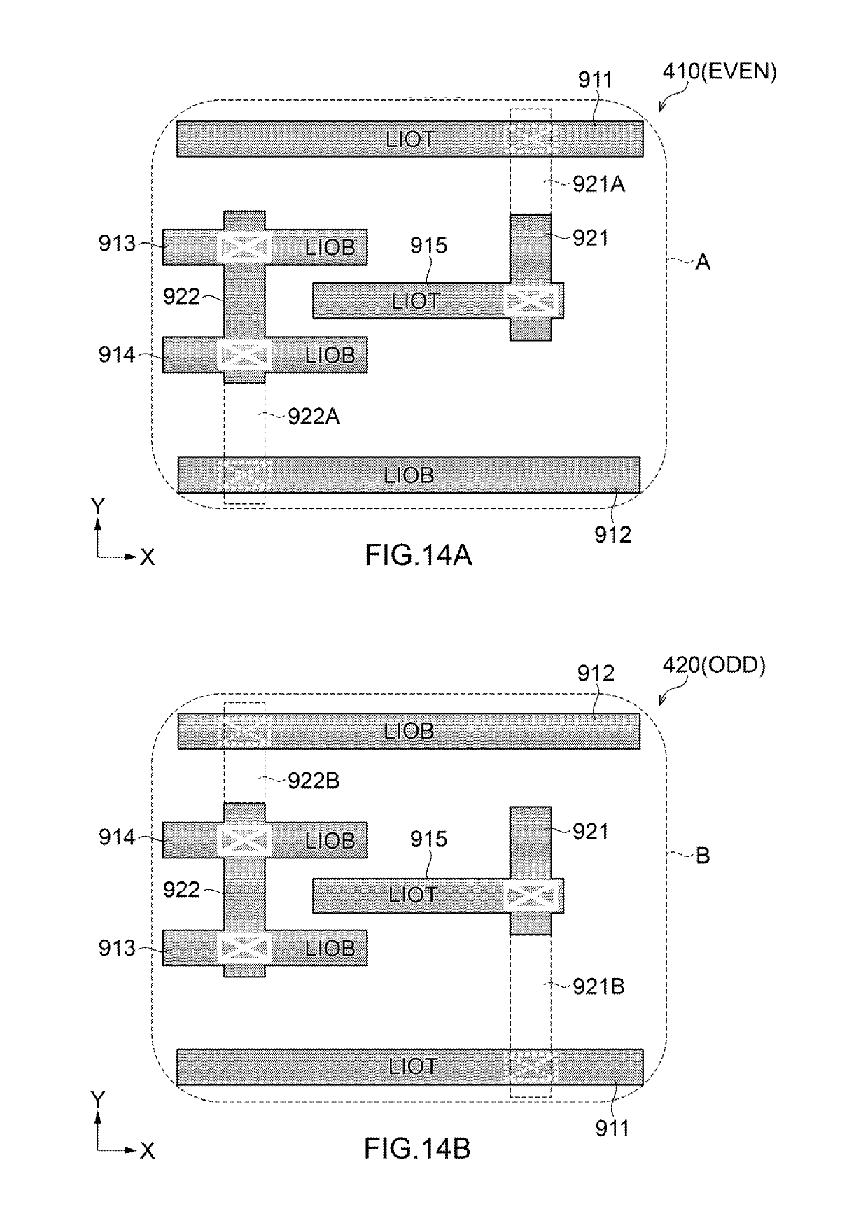

FIG. 14A is a diagram showing the wiring A shown in FIG. 13 in more detail. FIG. 14B is a diagram showing the wiring B shown in FIG. 13 in more detail. As shown in FIGS. 14A and 14B, both the wiring A and the wiring B include lines 911 to 915 formed in a conductor layer M1 as a lower layer and lines 921 and 922 formed in the conductor layer M2 as an upper layer. Among those lines, the lines 913 to 915 are arranged above the diffusion regions 810 to 813, 830 to 833, and 850 to 853 shown in FIG. 12 and coupled to the diffusion regions 810 to 813, 830 to 833, and 850 to 853, respectively. As shown in FIGS. 14A and 14B, the layout of the lines 911 to 915 included in the wiring A located in the sense amplifier region 410 on the EVEN side and the layout of the lines 911 to 915 included in the wiring B located in the sense amplifier region 420 on the ODD side are symmetric with each other. Further, as shown in FIG. 14A, by adding a line 921A to the line 921 coupled to the line 915, the added line 921A is coupled to the line 911, and by adding a line 922A to the line 922 coupled to the lines 913 and 914, the added line 922A is coupled to the line 912. Meanwhile, as shown in FIG. 14B, by adding a line 921B to the line 921 coupled to the line 915, the added line 921B is coupled to the line 911, and by adding a line 922B to the line 922 coupled to the lines 913 and 914, the added line 922B is coupled to the line 912. As described above, the sense amplifier region 410 on the EVEN side and the sense amplifier region 420 on the ODD side can have the same layout in the lines 911 to 915 located in the conductor layer M1 only by changing the position of the line to be added in the conductor layer M2.

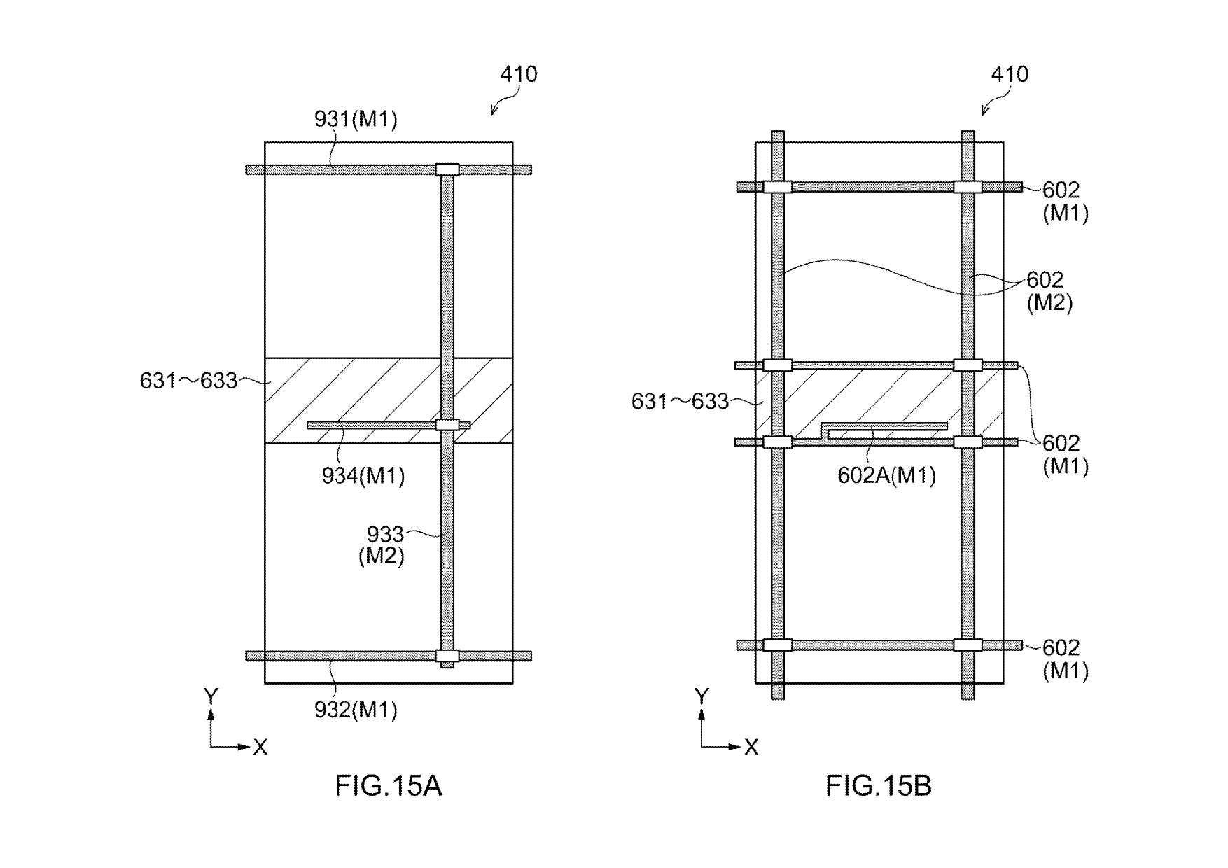

The ground potential VSS can be supplied to the diffusion regions 860 to 863 from power lines 931 and 932 arranged in the conductor layer M1 and extending in the X-direction at ends in the Y-direction of the sense amplifier region 410, as shown in FIG. 15A, via a power line 933 arranged in the conductor layer M2 and a power line 934 arranged in the conductor layer M1. Accordingly, it is possible to supply the ground potential VSS to the source of the transistor 633 included in the precharge circuit 630.

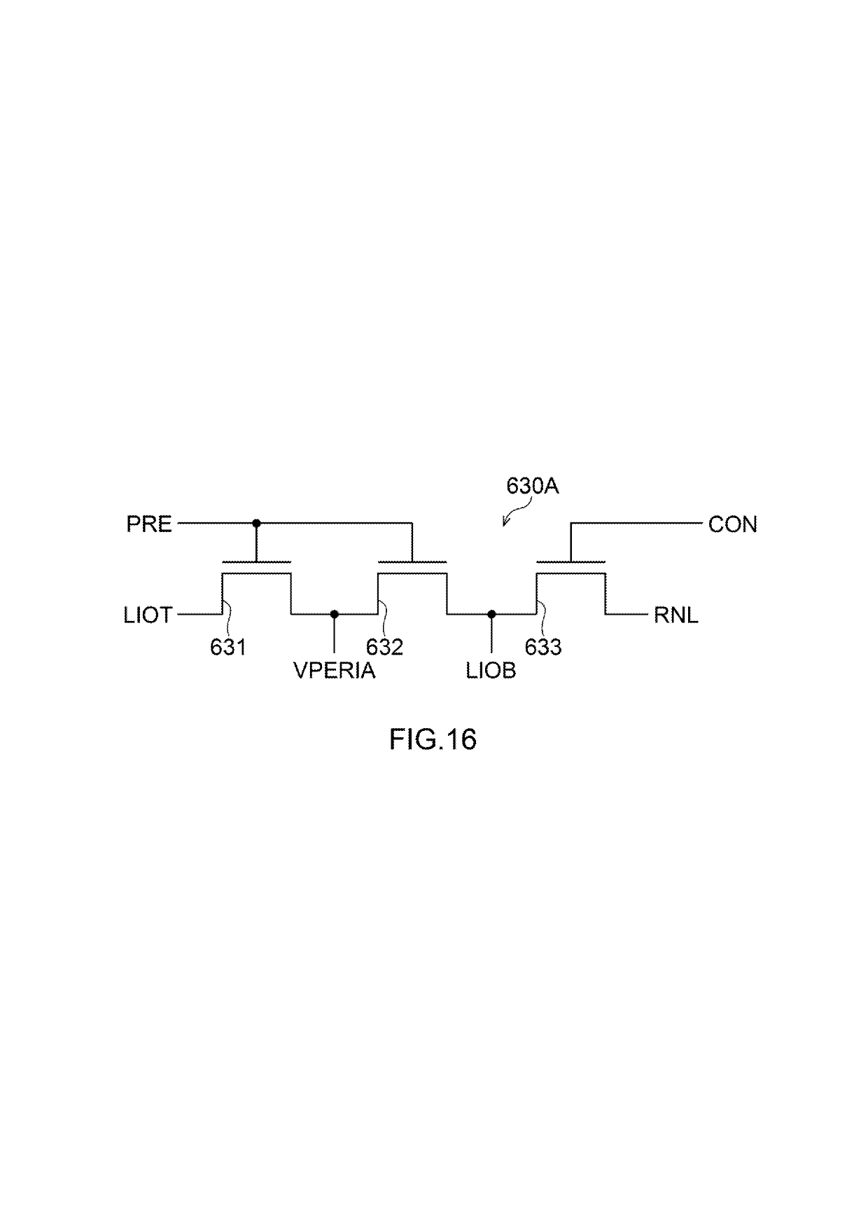

Alternatively, as in a precharge circuit 630A shown in FIG. 16, the source of the transistor 633 may be coupled to the source line 602 to which the source potential RNL is supplied. In this case, the local I/O line LIOB is coupled to a power line to which the ground potential VSS is supplied, via the transistor 633 and the transistor 601 shown in FIG. 7. With this configuration, an off leakage current through the transistor 633 is largely reduced, so that current consumption can be reduced. Further, as shown in FIG. 15B, the line 602 to which the source potential RNL is supplied is arranged in a mesh shape by using the conductor layers M1 and M2 on the sense amplifier region 410. Therefore, by providing a line 602A arranged in the conductor layer M1 and branching from the line 602 extending in the X-direction substantially at the center in the Y-direction of the sense amplifier region 410 or 420, it is possible to couple the line 602 to the diffusion regions 860 to 863 while minimizing addition of lines.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

What is claimed is:

1. An apparatus comprising:
first memory mats having a plurality of first bit line pairs;
second memory mats having one or more second bit line pairs for substituting for defective one or more of the plurality of first bit line pairs;
a sense amplifier circuit configured to amplify a potential difference between one of the second bit line pairs;
a first local I/O line coupled to a second bit line of the one of the second bit line pairs via a first column switch;
a second local I/O line coupled to another second bit line of one of the second bit line pairs via a second column switch;
a sub-amplifier circuit configured to drive a main I/O line based at least in part on a potential difference between the first local I/O line and the second local I/O line;
a precharge circuit configured to precharge each of the first local I/O line and the second local I/O line to a first power potential responsive to a first control signal; and
a discharge circuit configured to discharge the second local I/O line to a second power potential different from the first power potential responsive to a second control signal.

2. The apparatus of claim 1, wherein the first control signal is activated when the second memory mats are in a precharge state.

3. The apparatus of claim 2, wherein the second control signal is activated when the second memory mats are not selected in a read operation.

4. The apparatus of claim 3, wherein the second control signal is deactivated when the second memory mats are selected in the read operation.

5. The apparatus of claim 4,
wherein the sub-amplifier circuit includes first and second transistors coupled in series between the main I/O line and a power line supplied with the second power potential,
wherein the first transistor has a control electrode coupled to the second local I/O line, and
wherein the second transistor has a control electrode supplied with a third control signal activated in the read operation.

6. The apparatus of claim 5,
wherein the sub-amplifier circuit further includes third and fourth transistors coupled in series between the second local I/O line and the power line,
wherein the third transistor has a control electrode coupled to the main I/O line, and
wherein the fourth transistor has a control electrode supplied with a fourth control signal activated in a write operation.

7. The apparatus of claim 6,
wherein the sub-amplifier circuit further includes a fifth transistor coupled between the first local I/O line and the main I/O line, and
wherein the fifth transistor has a control electrode supplied with the fourth control signal.

8. The apparatus of claim 1,
wherein the precharge circuit includes:
a first transistor coupled between a first power line supplied with the first power potential and the first local I/O line; and
a second transistor coupled between the first power line and the second local I/O line, and
wherein the discharge circuit includes a third transistor coupled between a second power line supplied with the second power potential and the second local I/O line.

9. The apparatus of claim 8,
wherein each of the first and second transistors has a control electrode supplied with the first control signal, and
wherein the third transistor has a control electrode supplied with the second control signal.

10. The apparatus of claim 9, wherein at least a part of a diffusion region of the second transistor and at least a part of a diffusion region of the third transistor are shared.

11. The apparatus of claim 10, the second transistor is greater in size than the third transistor.

12. The apparatus of claim 9,
wherein the sense amplifier circuit includes fourth and fifth transistors cross coupled to each other and a driver circuit coupled between a common source of the fourth and fifth transistors and the second power line, and
wherein the third transistor is coupled between the second local I/O line and the common source.

13. An apparatus comprising:
first and second bit lines;
a sense amplifier circuit configured to amplify a potential difference between the first bit line and the second bit line such that one of the first and second bit lines is brought into a first potential and another one of the first and second bit lines is brought into a second potential;
a first local I/O line coupled to the first bit line via a first column switch;
a second local I/O line coupled to the second bit line via a second column switch;
a first transistor coupled between the first local I/O line and a first power line supplied with the first potential;
a second transistor coupled between the second local I/O line and the first power line; and
a third transistor coupled between the second local I/O line and a second power line supplied with the second potential,
wherein the first and second transistors are configured to be controlled by a first control signal, and
wherein the third transistor is configured to be controlled by a second control signal.

14. The apparatus of claim 13, further comprising a sub-amplifier circuit configured to drive a main I/O line based on a potential difference between the first and second local I/O lines,
wherein the sub-amplifier circuit includes fourth and fifth transistors coupled in series between the main I/O line and the second power line,
wherein the fourth transistor has a control electrode coupled to the second local I/O line, and
wherein the fifth transistor has a control electrode supplied with a third control signal activated in a read operation.

15. The apparatus of claim 14,
wherein the sub-amplifier circuit further includes sixth and seventh transistors coupled in series between the second local I/O line and the second power line,
wherein the sixth transistor has a control electrode coupled to the main I/O line, and
wherein the seventh transistor has a control electrode supplied with a fourth control signal activated in a write operation.

16. The apparatus of claim 15,
wherein the sub-amplifier circuit further includes an eighth transistor coupled between the first local I/O line and the main I/O line, and
wherein the eighth transistor has a control electrode supplied with the fourth control signal.

17. The apparatus of claim 16, wherein at least a part of a diffusion region of the second transistor and at least a part of a diffusion region of the third transistor are shared.

18. An apparatus comprising:
first and second bit lines;
a sense amplifier circuit configured to amplify a potential difference between the first bit line and the second bit line such that one of the first and second bit lines is brought into a first potential and another one of the first and second bit lines is brought into a second potential;
a first local I/O line coupled to the first bit line via a first column switch;
a second local I/O line coupled to the second bit line via a second column switch;
a first diffusion region coupled to the first local I/O line;
a second diffusion region operatively supplied with the first potential;
a third diffusion region coupled to the second local I/O line;
a fourth diffusion region operatively supplied with the second potential,
a first gate electrode covering a first channel region arranged between the first and second diffusion regions;
a second gate electrode covering a second channel region arranged between the second and third diffusion regions; and
a third gate electrode covering a third channel region arranged between the third and fourth diffusion regions,
wherein the first and second gate electrodes are short-circuited and supplied with a first control signal, and
wherein the third gate electrode is supplied with a second control signal.

19. The apparatus of claim 18, further comprising:
a fifth diffusion region operatively supplied with the first potential;
a sixth diffusion region coupled to the second local I/O line;
a fourth gate electrode covering a fourth channel region arranged between the first and fifth diffusion regions; and
a fifth gate electrode covering a fifth channel region arranged between the fifth and sixth diffusion regions,
wherein the first, second, fourth, and fifth gate electrodes are short-circuited and supplied with the first control signal.

20. The apparatus of claim 18,
wherein the sense amplifier circuit includes first and second transistors cross coupled to each other and a driver circuit coupled between a common source of the first and second transistors and a power line supplied with the second potential, and
wherein the fourth diffusion region is coupled to the common source.
